(19) United States
(12) Patent Application Publication
(10) Pub. No.: US 2022/0336407 A1
(43) Pub. Date: Oct. 20, 2022

(54) DIE BONDING STRUCTURES AND METHOD FOR FORMING THE SAME

(71) Applicant: AG MATERIALS TECHNOLOGY CO., LTD., Hsinchu City (TW)

(72) Inventors: Tung-Han CHUANG, Hsinchu City (TW); Hsing-Hua TSAI, Hsinchu City (TW)

(21) Appl. No.: 17/473,964

(22) Filed: Sep. 13, 2021

(30) Foreign Application Priority Data
Apr. 15, 2021 (TW) 110113489

(51) Int. Cl. H01L 23/00

(52) U.S. Cl. CPC H01L 24/83; H01L 24/29; H01L 24/27; H01L 2224/83192; H01L 2224/29147; H01L 2224/29155; H01L 2224/29239; H01L 2224/2908; H01L 2224/2745

(57) ABSTRACT

A die bonding structure is provided. The die bonding structure includes a chip, an adhesive layer under the chip, a bonding layer under the adhesive layer, and a heat dissipation substrate under the bonding layer. The bonding layer includes a silver nano-twinned thin film, which has parallel-arranged twin boundaries. The parallel-arranged twin boundaries include at least 90% of [111] crystal orientation.

### CROSS-REFERENCE TO RELATED APPLICATIONS

The present application claims priority of Taiwan Application No. 110113489, filed on Apr. 15, 2021, which is incorporated by reference herein in its entirety.

### BACKGROUND

### Technical Field

The disclosure relates to die bonding structures, and more particularly to die bonding structures of silver nano-twinned thin film.

### Description of the Related Art

The packaging process of a power IC chip includes wafer dicing, die bonding, wire bonding, molding, etc. The die bonding process requires a lower temperature to avoid damage to the power IC chips. It requires good thermal conductivity as well, so that the heat-dissipation performance of the power module during operation can be improved, and to ensure proper operation of the power module. In addition, the die bonding interface must have sufficient mechanical strength and reliability.

Traditionally, when die bonding a power module, a general solder alloy with a melting point below 250° C. is used. After bonding, the power modules cannot withstand higher operating temperatures because of the low melting point of the solder material.

Therefore, some packaging factories have begun to use Au20Sn, a high-temperature solder alloy with a melting point of 278° C., or other high-temperature solder types with different composition for soft soldering. Although their die bonding products have good thermal conductivity and temperature tolerance, their bonding temperature may reach over 300° C., which may cause direct failure of the LED components during the soldering process. In addition, after the high-temperature soldering, the thermal stress of cooling down to room temperature may also cause the bonding interface to crack. Therefore, the yield rate of the product is not high, and the material cost of the product is high. On the other hand, Au—Sn eutectic bonding can also be used. The back side of a power IC chip and the surface of a package substrate are first plated with a pure Au layer and a pure Sn layer is then plated on the Au layer, followed by heating at a temperature above the eutectic point in Au—Sn binary phase diagram. Thus, the eutectic reaction of the pure Au layer and the pure Sn layer between the power module IC chip and the heat dissipation substrate forms the Au-rich and Sn-rich eutectic alloy interface structure. Although this kind of power module also has good thermal conductivity and temperature tolerance, it can easily cause failures of the power module and damage to the package because of the high bonding temperature, and the material cost of the product is also high.

Furthermore, pure tin or pure indium thin film with a low melting point can also be used. The pure tin or pure indium thin film is melted at general soldering temperature and reacted with overlying and underlying copper, nickel or silver that has a high melting point to form an intermetallic compound. The bonding temperature of the film is not high, which can avoid damage to the interface caused by the thermal stress of the bonding, and the low melting point pure tin or pure indium film will be completely converted into a high melting point intermetallic compound after bonding, so it can be used at higher temperatures. However, the intermetallic compound is extremely brittle and also prone to interface cracking.

Sintering of silver powder or copper powder can also be used for die bonding, but under high-temperature sintering, there is still a very high risk of damage.

Taiwan Patent No. 16865724 discloses an electrical connection device and a method of electroplated copper nano-twinned thin films, in which two oxide substrates respectively plated with a metal layer are bonded at a pressure ranging from 0.8 to 3 MPa and a temperature ranging from 200° C. to 350° C. Taiwan Patent No. 1521104 discloses a package structure and a method thereof, in which a substrate is first electroplated with a copper seed layer then a nickel nano-twinned thin film, and two such substrates are bonded. Taiwan Patent No. 1519681 discloses a structure and a method thereof, in which a gold nano-twinned thin film is electroplated on the surface of a semiconductor wafer, a circuit board or a conductive substrate, and two such structures are then bonded to each other.

Although the prior art can form a large number of parallel-arranged nano-twinned thin films on substrates, they all use the rotary plating method with a high speed of 50 rpm or even up to 1500 rpm, which makes it difficult to control the process and the quality of the thin film, thus resulting in larger distance between twin boundaries and the preferred crystal orientation of the thin film being lower than 90%. For example, Taiwan Patent No. 1432613 shows an apparent Cu (222) crystal orientation in its XRD pattern. Taiwan Patent No. 1507548 shows a more obvious Au (222) crystal orientation, and its [111] preferred crystal orientation is even as low as only 50%. In addition, the size of the components or the contacts formed by electroplating will be limited, so generally the components or the contacts with a size smaller than 2 μm cannot be manufactured by electroplating methods. Sputtering or evaporation coating methods are less concerned in this regard. Even micro components or contacts with a size below 2 μm can be produced by sputtering or evaporation coating. In addition, the wastewater produced by electroplating process will also cause environmental concerns. The direct electroplating of nano-twins on silicon substrate has insufficient bonding force between the silicon substrate and the thin film, which may easily cause the thin film to peel off. Because the surface of the nano-twinned thin film lacks smoothness, when the nano-twinned thin film is used for the bonding of semiconductor wafers, circuit boards or conductive substrates in the prior art, a chemical mechanical polishing (CMP) process must be performed on the surface of the nano-twinned thin film to reduce the surface roughness. This not only complicates the process, but also destroys the nano-twinned thin film. In view of the above problems, the existing die bonding technology still faces many challenges.

### SUMMARY

Some embodiments of the present disclosure provide a die bonding structure including a chip, an adhesive layer under the chip, a bonding layer under the adhesive layer, and a heat dissipation substrate under the bonding layer. The bonding layer includes a silver nano-twinned thin film that has parallel-arranged twin boundaries. The parallel-arranged twin boundaries include at least 90% of [111] crystal orientation.

Some embodiments of the present disclosure provide a method for forming a die bonding structure, including: forming an adhesive layer on a chip; forming a bonding layer on the adhesive layer; and bonding the chip with a heat dissipation substrate through the bonding layer. The bonding layer includes a silver nano-twinned thin film, and the silver nano-twinned thin film has parallel-arranged twin boundaries. The parallel-arranged boundaries include at least 90% of [111] crystal orientation.

### BRIEF DESCRIPTION OF THE DRAWINGS

Aspects of this disclosure are best understood from the following detailed description when read with the accompanying figures. It should be noted that, in accordance with common practice in the industry, various features are not drawn to scale. In fact, the dimensions of the various features may be arbitrarily increased or reduced for clarity of discussion.

FIGS. 1-5 are cross-sectional views of a die bonding structure at different stages for forming the same according to some embodiments of the present disclosure.

FIGS. 6-8 are cross-sectional views of a die bonding structure at different stages for forming the same according to other embodiments of the present disclosure.

FIG. 9 is a focused ion beam (FIB) image showing a cross-sectional view of a Ti adhesive layer and a bonding layer formed on a single-crystalline silicon substrate by sputtering according to some embodiments of the present disclosure.

FIG. 10(a) is a FIB image showing a cross-sectional view of a Ti adhesive layer and a bonding layer formed on a single-crystalline germanium substrate by sputtering according to other embodiments of the present disclosure.

FIG. 10(b) is a FIB image showing a cross-sectional view of a bonding layer formed directly on a single-crystalline germanium substrate by sputtering according to other embodiments of the present disclosure.

FIG. 11 is a FIB image showing a cross-sectional view of a Ti adhesive layer and a bonding layer formed on a single-crystalline silicon carbide substrate by sputtering according to other embodiments of the present disclosure.

FIG. 12 is a FIB image showing a cross-sectional view of a Ti adhesive layer and a bonding layer formed on a single-crystalline silicon carbide substrate by evaporation coating according to other embodiments of the present disclosure.

FIG. 13 is a FIB image showing a cross-sectional view of a Ti adhesive layer and a bonding layer formed on a single-crystalline gallium arsenide substrate by sputtering according to other embodiments of the present disclosure.

FIG. 14 is a FIB image showing a cross-sectional view of a Ti adhesive layer and a bonding layer formed on a single-crystalline gallium arsenide substrate by evaporation coating according to other embodiments of the present disclosure.

FIG. 15 is a FIB image showing a cross-sectional view of a single-crystalline silicon substrate covered with a Ti adhesive layer and a bonding layer formed by sputtering bonded with a ceramic substrate according to other embodiments of the present disclosure.

FIG. 16 is a FIB image showing a cross-sectional view of a single-crystalline silicon carbide substrate covered with a Ti adhesive layer and a bonding layer formed by sputtering bonded with a ceramic substrate according to other embodiments of the present disclosure.

### DETAILED DESCRIPTION

The following disclosure provides many different embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Some variations of embodiments are described below. In different figures and illustrated embodiments, similar element symbols are used to indicate similar elements. It is appreciated that additional operations can be provided before, during, and/or after the stages described in these embodiments. Some of the stages that are described can be replaced or eliminated for different embodiments.

Furthermore, spatially relative terms, such as “beneath,” “below,” “lower,” “overlapped,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Furthermore, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Embodiments of the present disclosure provide a die-bonding structure with silver nano-twins, which enables the chip can be bonded with a heat dissipation substrate under a low temperature of about 100° C. to about 200° C. to ensure the process yield and good bonding strength of the power module packaging. Furthermore, no cracking occurs at the bonding interface by high-temperature thermal stress, thus improving the reliability of the power module product application.

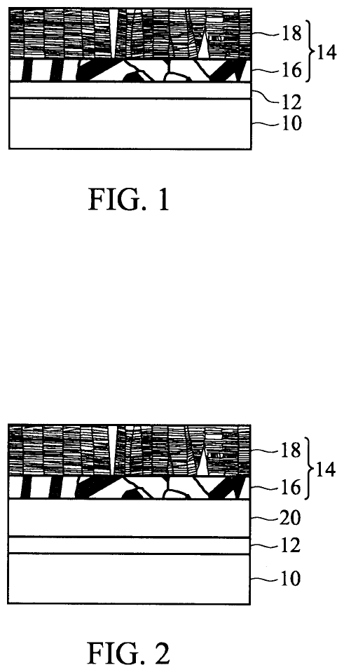

In accordance with some embodiments, FIGS. 1-5 illustrate cross-sectional views of a die bonding structure at different stages for forming the same. First referring to FIG. 1, an adhesive layer 12 and a bonding layer 14 are sequentially formed on a chip 10. In accordance with some embodiments, the chip 10 includes single crystal of silicon, germanium, gallium arsenide, gallium nitride, or silicon carbide. In accordance with some embodiments, the chip 10 is a power IC chip.

In accordance with some embodiments, the adhesive layer 12 includes titanium, chromium or titanium tungsten. In accordance with some embodiments, the thickness of the adhesive layer 12 is about 0.1 μm to about 0.5 μm. It should be understood that the thickness of the adhesive layer may be appropriately adjusted according to practical applications, and is not intended to be limiting. The adhesive layer can provide better bonding force between the chip and the bonding layer and has the effect of lattice buffering at the same time.

In some embodiments, the adhesive layer 12 may be formed on the substrate 10 by sputtering. In some embodiments, the sputtering may use single sputtering gun or multiple sputtering guns. In the sputtering process, the power source may be DC, DC plus, RF, or high-power impulse magnetron sputtering (HIPIMS). The power may be, for example, about 100 W to about 200 W. The processing temperature is room temperature, but during the sputtering process it will rise by about 50° C. to about 200° C. The deposition rate of the adhesive layer 12 may be, for example, about 0.1 nm/second to about 0.3 nm/second. The back pressure is less than 1×10⁻⁵ torr. The working pressure may be, for example, about 1×10⁻³ torr to about 1×10⁻² torr. The argon flow may be, for example, about 10 sccm to about 20 sccm. The rotation speed of the chuck may be, for example, about 5 rpm to about 20 rpm. The bias voltage applied to the substrate during the sputtering process is about −100V to about −200V. It should be understood that the sputtering process parameters described above may be appropriately adjusted according to practical applications, and are not intended to be limiting.

In accordance with other embodiments, the adhesive layer 12 may be formed on the chip 10 by evaporation coating. In some embodiments, the back pressure of the evaporation coating process is less than 1×10⁻⁵ torr, and the working pressure of the process may be, for example, about 1×10⁻⁴ torr to about 5×10⁻⁴ torr. The argon flow may be about 2 sccm to about 10 sccm. The rotation speed of the chuck may be, for example, about 5 rpm to about 20 rpm. The evaporation coating rate of the adhesive layer 12 may be, for example, about 0.05 nm/second to about 0.3 nm/second. It should be understood that the evaporation coating process parameters described above may be appropriately adjusted according to practical applications, and are not intended to be limiting.

Compared with sputtering or evaporation coating, the size of components or contacts will be limited by electroplating process. In detail, the components or the contacts with a size smaller than 2 microns generally cannot be manufactured by electroplating. In contrast, the components or the contacts with a size even below 2 microns can be easily manufactured by sputtering or evaporation coating.

The adhesive layer of the present disclosure can improve the bonding force between the subsequent bonding layer and the chip to avoid peeling. If the nano-twinned thin film is sputtered directly on the chip, the thickness of the thin film can only reach about 2 microns due to the insufficient bonding force between the nano-twinned thin film and the chip.

In addition, the crystal orientation of the chip will affect the thin film formed directly thereon. For example, the thin film having a (111) crystal orientation is not easily formed on the chip having a (100) crystal orientation. Therefore, the silver nano-twinned thin film with high twin density can be obtained only when the silver nano-twinned thin film is formed on the chip having a (111) crystal orientation, whereas the silver nano-twinned structure formed on the (110) chip having a (111) crystal orientation has very low twin density. However, the adhesive layer in the present disclosure has the lattice buffering effect on forming the silver nano-twinned structure on the chip with different crystal orientations. In detail, no matter the crystal orientation of the chip is (100), (110), or (111), the formed nano-twins all have at least 90% of [111] crystal orientation.

It should be understood that the adhesive layer can not only form the silver nano-twinned structure having a (111) crystalline orientation on the above chips having a (100), (110), or (111) crystal orientation, for other chips such as SiC, GaAs, etc., it also has the effect of reducing the influence of the crystal orientation of the chips on the crystal orientation of the subsequent deposited twin structure.

Still referring to FIG. 1, the thickness of the bonding layer 14 is over 2.0 μm, for example, about 2.0 μm to about 15 μm, and the bonding layer 14 includes a parallel-arranged silver nano-twinned thin film 18 with a thickness at least 1.5 μm, for example, about 1.5 μm to about 10 μm. In accordance with some embodiments, the distance between the boundaries of the silver nano-twinned thin film 18 is about 1 μm to about 100 nm. The parallel-arranged twin boundaries includes at least 90% of (for example, over 90% or over 95%) [111] preferred crystal orientation, and the silver nano-twinned thin film 18 with [111] preferred crystal orientation occupies at least 80% of an entirety of the bonding layer 14. In accordance with some embodiments, the bonding layer 14 further includes a transition grain layer 16. When the bonding layer 14 is initially formed on the adhesion layer 12, the bonding layer 14 does not form the silver nano-twinned thin film 18 with parallel-arranged twin boundaries immediately but forms the transition grain layer 16 without parallel-arranged twin boundaries. In some embodiments, the thickness of the transition grain layer 16 is, for example, about 0.1 μm to about 1 μm.

In practice, regardless of electroplating, sputtering or evaporation coating, when the thickness of the nano-twinned thin film is greater than 2 μm, the bonding force between the nano-twinned thin film and the chip has been significantly deteriorated, and it is easy to peel off. The present invention applies the adhesive layer 12 on the chip before the formation of the nano-twinned thin film, which can ensure that even when the thickness of the nano-twinned thin film exceeds 10 μm, it still maintains a good bonding force with the chip.

In addition, when the thickness of the nano-twinned thin film is less than 2 microns, in the subsequent low-temperature and low-pressure wafer bonding and 3D-IC flip chip assembly processes, the nano-twinned thin film may be consume due to the rapid reaction with the bonding material, and there will be no bonding force between the intermetallic compound formed at the interface and the chip, which will cause the interface to peel off.

In accordance with some embodiments, the bonding layer 14 may be formed on the adhesive layer 12 by sputtering. In some embodiments, the sputtering may use single sputtering gun or multiple sputtering guns. In the sputtering process, the power source may be DC, DC plus, RF, or high-power impulse magnetron sputtering (HIPIMS). The power of the sputtering of the bonding layer 14 may be, for example, about 100 W to about 500 W. The processing temperature is room temperature, but during the sputtering process it will rise by about 50° C. to about 200° C. The deposition rate of the bonding layer 14 may be, for example, about 0.5 nm/second to about 3 nm/second. The back pressure is less than 1×10⁻⁵ torr. The working pressure may be, for example, about 1×10⁻³ torr to about 1×10⁻² torr. The argon flow may be, for example, about 10 sccm to about 20 sccm. The rotation speed of the chuck may be, for example, 5 rpm to 20 rpm. The bias voltage applied to the substrate during the sputtering process is about −100V to about −200V. It should be understood that the sputtering process parameters described above may be appropriately adjusted according to practical applications, and are not intended to be limiting.

In accordance with other embodiments, the bonding layer 14 may be formed on the adhesive layer 12 by evaporation coating. In some embodiments, the back pressure of the evaporation coating process is less than 1×10⁻⁵ torr, and the working pressure of the process may be, for example, about 1×10⁻⁴ torr to about 5×10⁻⁴ torr. The argon flow may be about 2 sccm to about 10 sccm. The rotation speed of the chuck may be, for example, about 5 rpm to about 20 rpm. The evaporation coating rate of the bonding layer 14 may be, for example, about 1 nm/second to about 5 nm/second. During the evaporation process, an ion impact is applied to the bonding layer 14. The voltage is about 10V to about 300V, and the current is about 0.1 A to about 1.0 A. It should be understood that the evaporation coating process parameters described above may be appropriately adjusted according to practical applications, and are not intended to be limiting.

Referring to FIG. 2, in accordance with other embodiments, the adhesive layer 12, the diffusion barrier layer 20 and the bonding layer 14 are formed on the chip 10 sequentially. The adhesive layer 12 can be formed on the surface of the chip 10 with reference to the embodiment shown in FIG. 1, so it will not be repeated here. In this embodiment, a diffusion barrier layer 20 is additionally formed on the adhesive layer 12. Afterwards, the bonding layer 14 can be formed on the diffusion barrier layer 20 with reference to the embodiment shown in FIG. 1.

According to some embodiments, the diffusion barrier layer 20 includes nickel or copper, and according to some embodiments, the thickness of the diffusion barrier layer 20 is over 0.1 μm. For example, about 0.1 μm to about 0.5 μm. The diffusion barrier layer can further enhance the bonding force between the adhesive layer and the subsequently formed bonding layer and prevent the subsequently formed bonding layer from diffusing toward the chip or prevent the adhesive layer from diffusing toward the subsequently formed bonding layer.

In some embodiments, the diffusion barrier layer 20 may be formed on the adhesive layer 12 by sputtering. In some embodiments, the sputtering may use single sputtering gun or multiple sputtering guns. In the sputtering process, the power source may be DC, DC plus, RF, or high-power impulse magnetron sputtering (HIPIMS). The processing temperature is room temperature, but during the sputtering process it will rise by about 50° C. to about 200° C. The back pressure is less than 1×10⁻⁵ torr. The working pressure may be, for example, about 1×10⁻³ torr to about 1×10⁻² torr. The argon flow may be, for example, about 10 sccm to about 20 sccm. The rotation speed of the chuck may be, for example, about 5 rpm to about 20 rpm. The bias voltage applied to the substrate during the sputtering process is about −100V to about −200V. The deposition rate of the diffusion barrier layer 20 may be, for example, about 0.5 nm/second to about 3 nm/second. It should be understood that the sputtering process parameters described above may be appropriately adjusted according to practical applications, and are not intended to be limiting.

In accordance with other embodiments, the diffusion barrier layer 20 may be formed on the adhesive layer 12 by evaporation coating. In some embodiments, the back pressure of the evaporation coating process is less than 1×10⁻⁵ torr, and the working pressure of the process may be, for example, about 1×10⁻⁴ torr to about 5×10⁻⁴ torr. The argon flow may be about 2 sccm to about 10 sccm. The rotation speed of the chuck may be, for example, about 5 rpm to about 20 rpm. The evaporation coating rate of the diffusion barrier layer 20 may be, for example, about 1 nm/second to about 5 nm/second. It should be understood that the evaporation coating process parameters described above may be appropriately adjusted according to practical applications, and are not intended to be limiting.

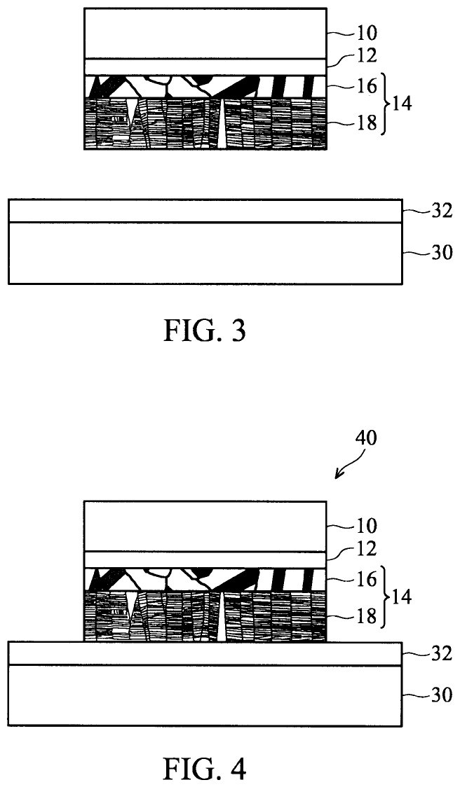

Accordance to some embodiments, FIG. 3 illustrates a heat dissipation substrate 30 to be bonded with the chip 10. The heat dissipation substrate 30 is a printed circuit board covered with a copper circuit layer 32. In other embodiments, the heat dissipation substrate 30 is a metal heat sink or a ceramic substrate. The ceramic substrate above includes: alumina, aluminum nitride, or silicon nitride.

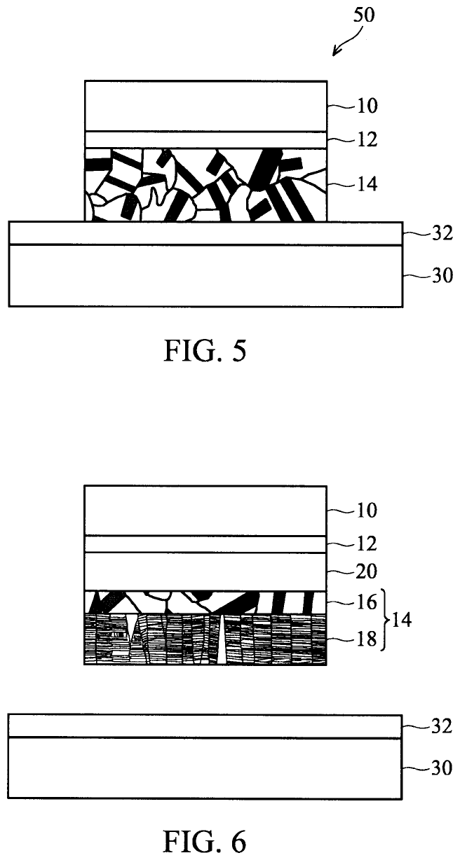

Referring to FIGS. 4-5, according to some embodiments, the chip 10 as shown in FIG. 1 is laminated on the substrate 30 as shown in FIG. 3 through the bonding layer 14, and die bonding is performed. According to some embodiments, the die bonding can be performed in a vacuum or a protective atmosphere, and the temperature can range from about 100° C. to about 300° C., for example, about 100° C. to about 150° C. or about 120° C. to about 180° C. The pressure can range from about 5 MPa to about 30 Mpa, for example, about 5 MPa to about 10 MPa or about 15 MPa to about 20 MPa. In such pressure range, regardless of the chip or the silver nano-twins can be kept intact. Although the conventional techniques can perform the bonding process at a low pressure of 0.8 MPa to 3 MPa, it is necessary to perform chemical mechanical polishing (CMP) on the nano-twinned thin film before bonding to reduce the surface roughness. It not only complicates the process but also destroys the nano-twinned thin film. Under the premise of not damaging the chip and the silver nano-twin, the present invention applies a pressure of about 5 MPa to about 30 Mpa (which is higher than the conventional techniques) to make the protruding surface structure of the silver nano-twins undergo nano-level plastic deformation to achieve close contact. It not only solves the surface roughness problem of the silver nano-twins, but also eliminates the need for additional complicated chemical mechanical polishing steps in conventional techniques, which greatly improves the productivity and the yield. Since the hardness of the copper nano-twins of the conventional techniques is as high as 4 GPa, which is about twice the hardness of the silver nano-twins of the present invention, if the plastic deformation mechanism of the nano-level protruding structure in the present invention is used to solve the surface roughness problem of copper nano-twins, a pressure of more than 100 MPa must be applied, which will cause damage to the chip and the nano-twins.

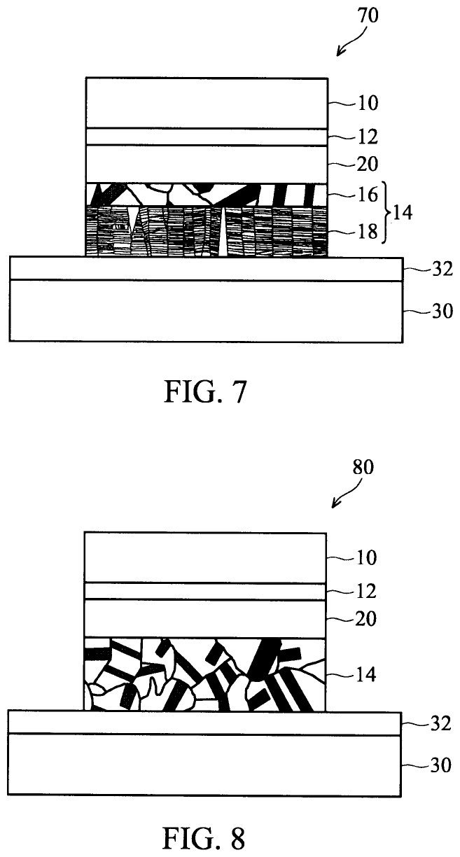

According to some embodiments, the chip 10 and the substrate 30 are bonded at a temperature below 200° C. to form the die-bonding structure 40 as shown in FIG. 4, wherein the bonding layer 14 includes the silver nano-twinned thin film 18 and the transition grain layer 16. According to some other embodiments, the chip 10 and the substrate 30 are bonded at a temperature above 200° C. to form the die bonding structure 40 as shown in FIG. 5, wherein the silver nano-twinned thin film 18 and the transition grain layer 16 in the bonding layer 14 are transformed into ordinary crystal grains through the high temperature. It is appreciated that diffusion barrier layer 20 can be formed between the adhesive layer 12 and the bonding layer 14 as shown in FIG. 3 to FIG. 5, and the resulting structures are shown in FIG. 6 to FIG. 8.

The present disclosure can perform the bonding process at low temperature and low pressure, so that the semiconductor device is not affected by the high temperature of bonding process. In detail, compared to the silver nano-twinned structure, the copper nano-twinned structure requires a higher temperature (for example, higher than 200° C.) and a higher pressure (for example, higher than 30 MPa) for bonding process, which may cause damage to the semiconductor device.

The formation of a twin structure is due to the accumulated strain energy inside a material. The strain energy drives uniform atomic shear to unsheared atoms at some regions inside the grain to form lattice positions that are mirror-symmetrical to each other. Twins include annealing twins and mechanical twins. The mutually symmetrical interface is the twin boundary.

Twins are mainly formed in face centered cubic (FCC) or hexagonal closed-packed (HCP) crystalline materials with the closest lattice arrangement. In addition to the crystal structure with the closest lattice arrangement, twins are more likely formed in materials with small stacking fault energy.

Twin boundaries are coherent crystal structures and are classified as Σ3 and Σ9 special grain boundaries with low interfacial energy. The crystal orientations are all {111}. Compared with high-angle grain boundaries formed by general annealing and recrystallization, the interfacial energy of twin boundaries is about 5% of the interfacial energy of high-angle grain boundaries (George E. Dieter, Mechanical Metallurgy, McGRAW-HILL Book Company, 1976, P. 135-141).

Due to the low interfacial energy of the twin boundaries, oxidation, sulfurization, and chloride ion corrosion may be avoided. Therefore, the silver nano-twinned thin film exhibits better resistance to oxidation and corrosion. In addition, the symmetrical lattice arrangement of twins is less likely to impede electron transportation. Therefore, the silver nano-twinned thin film exhibits better electrical and thermal conductivity. Because the twin boundaries inhibit the movement of dislocation, materials may still maintain high tensile strength. The characteristics of high tensile strength and electrical conductivity have been proven in the copper thin film. (See Ultrahigh Strength and High Electrical Conductivity in Copper, Science, vol. 304, 2004, p. 422-426 issued to L. Lu, Y. Shen, X. Chen, L. Qian, and K. Lu).

In terms of high-temperature stability, twin boundaries are more stable than high-angle grain boundaries due to the low interfacial energy of twin boundaries. Twin boundaries are less likely to move at high temperatures. Twin boundaries may have an effect on locking surrounding high-angle grain boundaries, making the high-angle grain boundaries unable to move. Therefore, the grains may not grow significantly at high temperatures, which enable the tensile strength of the material to be maintained at high temperatures.

In terms of current reliability, since atoms have a low diffusion rate when passing through twin boundaries with low interfacial energy, it is difficult to move atoms inside the wire at a high current density during operation of electronic devices. As such, the electromigration that often occurs when current passes through a wire is inhibited. It has been proven that twins can inhibit electromigration in copper thin film. (See Observation of Atomic Diffusion at Twin-Modified Grain Boundaries in Copper, Science, vol. 321, 2008, p. 1066-1069 issued to K. C. Chen, W. W. Wu, C. N. Liao, L. J. Chen, and K. N. Tu).

In addition, the resistivity of silver is 1.63 μΩ·cm, which is lower than that of copper (1.69 μΩ·cm), gold (2.2 μΩ·cm), and nickel (6.90 μΩ·cm). The stacking fault energy of silver is 25 mJ/m², which is also lower than that of copper (70 mJ/m²), gold (45 mJ/m²), and nickel (225 mJ/m²). Therefore, silver is more likely to form twins than copper, gold and nickel. Compared to the conventional techniques for forming copper nano-twinned thin films by electroplating, the diffusion rate of silver in the sputtering or evaporation coating process for forming silver nano-twinned thin film of the present disclosure is more than 10 times faster than that of copper. The melting point of silver is about 100° C. lower than that of copper. Therefore, die bonding processes can be performed at a lower temperature. Besides, the hardness of silver nano-twins are only about 2 GPa, which is softer than copper nano-twins, so the surface roughness has smaller effect on the bonding process, and the coplanarity problem is less likely to occur especially when there is a differences in the height of the micro components or the contacts. Furthermore, compared with copper nano-twinned thin films, silver is less susceptible to oxidation, so it has better reliability. In conventional techniques, although the bonding process can be performed at a low pressure of 0.8 Mpa to 3 Mpa, a CMP process must be performed on the surface of the nano-twinned thin film first. Under the premise of not damaging the chip and the silver nano-twins, the invention of the present disclosure applies a pressure of about 5 MPa to about 30 Mpa (which is higher than the conventional techniques) to make the protruding surface structure of the silver nano-twins undergo nano-level plastic deformation to achieve close contact. It not only solves the surface roughness problem of silver nano-twins, but also eliminates the need for additional CMP steps in conventional techniques, which greatly improves the productivity and the yield. These characteristics all shows the silver nano-twinned thin films in the embodiments of the present disclosure have better market application advantages. Especially for the semiconductor industry needs such as low temperature die bonding.

Some working examples of the bonding structure of the present disclosure and their test results are described in detail below.

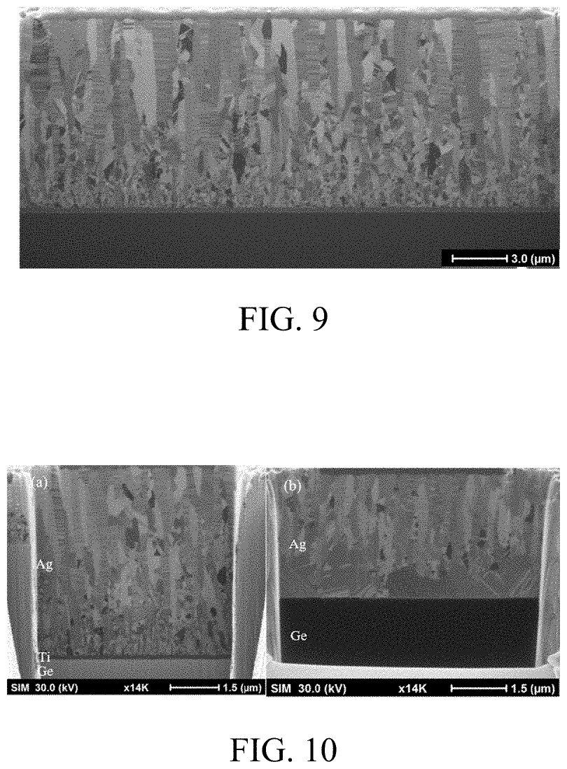

A 0.3 μm Ti adhesive layer and a 10 μm bonding layer were formed on the surface of a single-crystalline Si chip by sputtering. FIG. 9 shows the cross-sectional metallographic image of the structure analyzed by focused ion beam (FIB). The height of the silver nano-twinned thin film was 8 μm, and there was a transition grain layer of about 2 μm thick between the Ti adhesive layer and the silver nano-twinned thin film.

A 0.3 μm Ti adhesive layer and a 6 μm bonding layer were formed on the surface of a single-crystalline Ge chip by sputtering. FIG. 10(a) shows the cross-sectional metallographic image of the structure analyzed by FIB. The height of the silver nano-twinned thin film was 5 μm, and there was a transition grain layer of about 1 μm thick between the Ti adhesive layer and the silver nano-twinned thin film.

A 3 μm bonding layer was formed directly on the surface of a single-crystalline Ge chip by sputtering. FIG. 10(b) shows the cross-sectional metallographic images of the structure analyzed by FIB. The height of the silver nano-twinned thin film was 2.5 μm, and there was a transition grain layer of about 0.5 μm thick between the chip and the silver nano-twinned thin film.

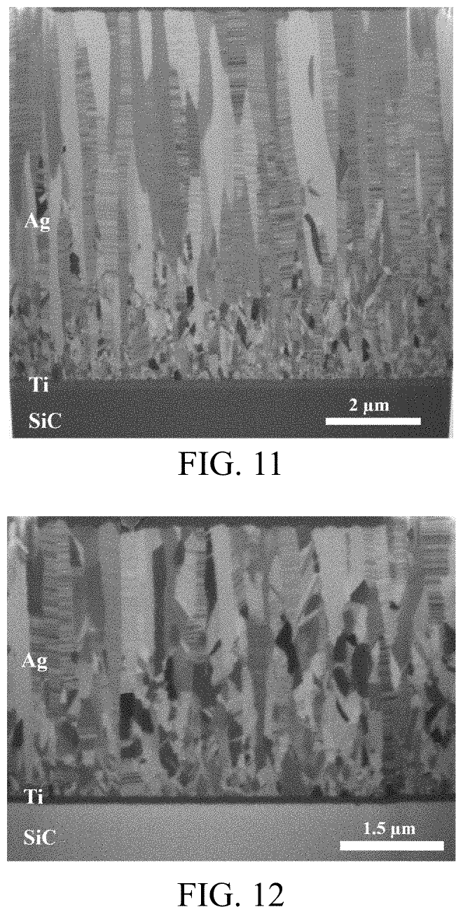

A 0.3 μm Ti adhesive layer and an 8 μm bonding layer were formed on the surface of a single-crystalline SiC chip by sputtering. FIG. 11 shows the cross-sectional metallographic images of the structure analyzed by FIB. The height of the silver nano-twinned thin film was 6.5 μm, and there was a transition grain layer of about 1.5 μm thick between the Ti adhesive layer and the silver nano-twinned thin film.

A 0.3 μm Ti adhesive layer and a 4 μm bonding layer were formed on the surface of a single-crystalline SiC chip by evaporation coating. FIG. 12 shows the cross-sectional metallographic images of the structure analyzed by FIB. The height of the silver nano-twinned thin film was 3.5 μm, and there was a transition grain layer of about 0.5 μm thick between the Ti adhesive layer and the silver nano-twinned thin film.

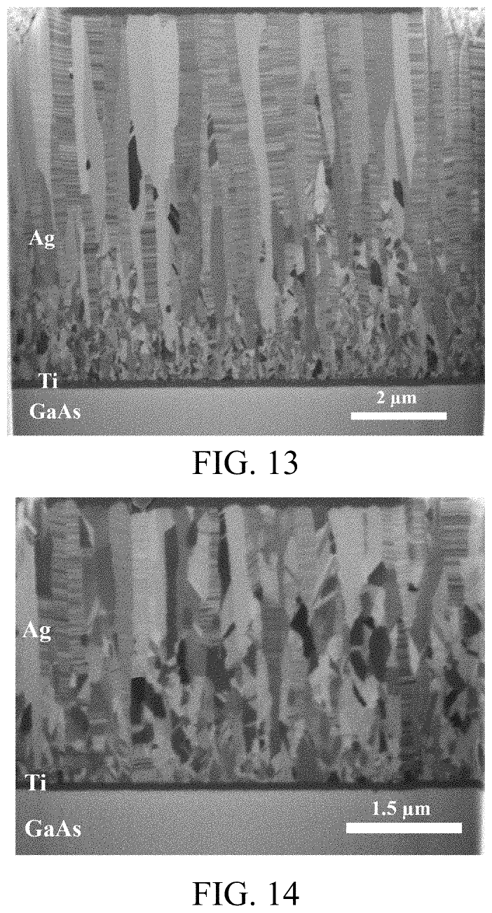

A 0.2 μm Ti adhesive layer and an 8 μm bonding layer were formed on the surface of a single-crystalline GaAs chip by sputtering. FIG. 13 shows the cross-sectional metallographic images of the structure analyzed by FIB. The height of the silver nano-twinned thin film was 7 μm, and there was a transition grain layer of about 2 μm thick between the Ti adhesive layer and the silver nano-twinned thin film.

A 0.2 μm Ti adhesive layer and a 6 μm bonding layer were formed on the surface of a single-crystalline GaAs chip by evaporation coating. FIG. 14 shows the cross-sectional metallographic images of the structure analyzed by FIB. The height of the silver nano-twinned thin film was 4 μm, and there was a transition grain layer of about 0.5-2 μm thick between the Ti adhesive layer and the silver nano-twinned thin film.

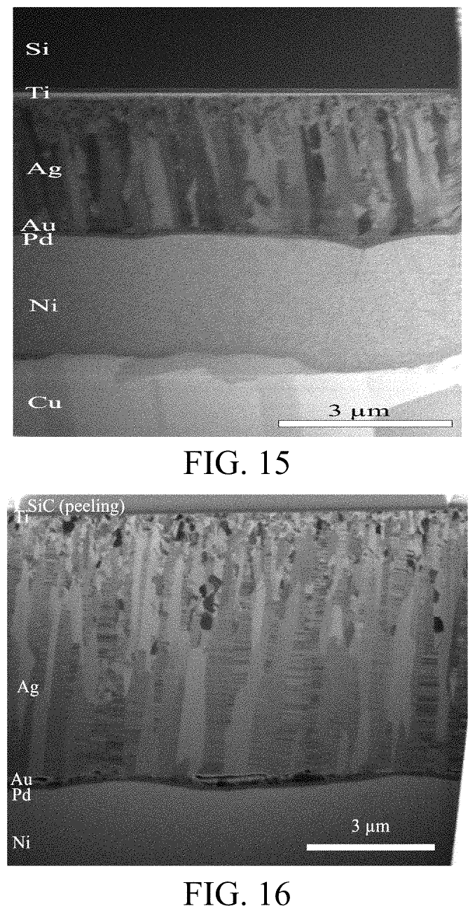

After the single-crystalline Si surface shown in FIG. 15 was plated with a silver nano-twinned thin film by sputtering, it was bonded with an alumina ceramic substrate covered with Cu/Ni/Pd/Au. FIG. 15 shows the cross-sectional metallographic images of the structure analyzed by FIB. The height of the silver nano-twinned thin film was 2 μm, and there were no voids at bonding interface between the silver nano-twinned thin film and the ceramic substrate.

After the single-crystalline SiC surface shown in FIG. 16 was plated with a silver nano-twinned thin film by sputtering, it was bonded with an alumina ceramic substrate covered with Cu/Ni/Pd/Au. FIG. 16 shows the cross-sectional metallographic images of the structure analyzed by FIB. The height of the silver nano-twinned thin film was 6 μm, and there were no voids at bonding interface between the silver nano-twinned thin film and the ceramic substrate.

The embodiments of the present disclosures have some advantageous features. The adhesive layer between the chip and the bonding layer provides better bonding force between the chip and the bonding layer to avoid peeling. The adhesive layer also has the lattice buffering effect on reducing the influence of the crystal orientation of the chip on the epitaxial growth of the silver nano-twinned thin film. In the cross-sectional metallographic images, the silver nano-twinned thin film includes parallel-arranged twin boundaries, and occupies at least 40% of an entirety of the twin boundaries. Furthermore, the parallel-arranged twin boundaries include at least 90% of [111] crystal orientation. Silver nano-twinned thin film accounts for at least 80% of the overall bonding layer. In addition, silver has lower resistivity, stacking energy, and melting point comparing with other metals (such as copper, gold, nickel, etc.). It is easier to from nano-twinned structure and to perform bonding structure at low temperature and low pressure with silver.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A die bonding structure, comprising:
a chip;
an adhesive layer under the chip;
a bonding layer under the adhesive layer, wherein the bonding layer comprises a silver nano-twinned thin film, and the silver nano-twinned thin film has parallel-arranged twin boundaries, wherein the parallel-arranged twin boundaries comprise at least 90% of [111] crystal orientation; and
a heat dissipation substrate under the bonding layer.

2. The die bonding structure as claimed in claim 1, wherein the chip comprises a single crystal of silicon, germanium, gallium arsenide, gallium nitride or silicon carbide.

3. The die bonding structure as claimed in claim 1, wherein the chip is a power IC chip.

4. The die bonding structure as claimed in claim 1, wherein the adhesive layer comprises titanium, chromium, or titanium tungsten.

5. The die bonding structure as claimed in claim 1, wherein the adhesive layer has a thickness of 0.1 μm to 0.5 μm.

6. The die bonding structure as claimed in claim 1, wherein the bonding layer has a thickness of at least 2.0 μm, and the bonding layer comprises the silver nano-twinned thin film at least 1.5 μm thick.

7. The die bonding structure as claimed in claim 1, wherein a distance between the parallel-arranged twin boundaries is between 1 nm and 100 nm, and the silver nano-twinned thin film with [111] crystal orientation occupies at least 80% of the bonding layer.

8. The die bonding structure as claimed in claim 1, wherein the dissipation substrate comprises a printed circuit board covered with a copper circuit layer, a metal heat sink, or a ceramic substrate.

9. The die bonding structure as claimed in claim 1, wherein the bonding layer further comprises a transition grain layer between the silver nano-twinned thin film and the adhesive layer.

10. The die bonding structure as claimed in claim 1, which further comprises a diffusion barrier layer between the bonding layer and the adhesive layer.

11. The die bonding structure as claimed in claim 10, wherein the diffusion barrier layer comprises nickel or copper.

12. The die bonding structure as claimed in claim 10, wherein the diffusion barrier layer has a thickness of at least 0.1 μm.

13. A method for forming a die bonding structure, comprising:
forming an adhesive layer on a chip;
forming a bonding layer on the adhesive layer; and
bonding the chip with a heat dissipation substrate through the bonding layer, wherein the bonding layer comprises a silver nano-twinned thin film, and the silver nano-twinned thin film has parallel-arranged twin boundaries, wherein the parallel-arranged boundaries comprise at least 90% of [111] crystal orientation.

14. The method as claimed in claim 13, wherein the chip comprises a single crystal of silicon, germanium, gallium arsenide, gallium nitride, or silicon carbide.

15. The method as claimed in claim 13, wherein the dissipation substrate comprises a printed circuit board covered with a copper circuit layer, a metal heat sink, or a ceramic substrate.

16. The method as claimed in claim 13, wherein the step of forming the adhesive layer and the bonding layer comprises sputtering or evaporation coating.

17. The method as claimed in claim 13, wherein the step of bonding the chip with the heat dissipation substrate is performed at a temperature of 100° C. to 250° C.

18. The method as claimed in claim 13, wherein the step of bonding the chip with the heat dissipation substrate is performed under 5 Mpa to 30 Mpa of pressure.

19. The method as claimed in claim 13, further comprising:
forming a transition grain layer between the adhesive layer and the silver nano-twinned thin film.

20. The method as claimed in claim 13, further comprising:
forming a diffusion barrier layer between the adhesive layer and the bonding layer by sputtering or evaporation coating.
